(19) United States
(12) Patent Application Publication
(10) Pub. No.: US 2024/0098996 A1
(43) Pub. Date: Mar. 21, 2024

(54) THREE-DIMENSIONAL SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventors: Siyeong Yang, Suwon-si (KR); Sunggil Kim, Suwon-si (KR); Yuyeon Kim, Suwon-si (KR); Jumi Bak, Suwon-si (KR)

(21) Appl. No.: 18/317,274

(22) Filed: May 15, 2023

(30) Foreign Application Priority Data
Sep. 21, 2022 (KR) 10-2022-0119510

(51) Int. Cl. H10B 43/27; H01L 23/00; H01L 23/522; H01L 23/528; H01L 25/065; H10B 41/10; H10B 41/27; H10B 41/35; H10B 41/40; H10B 43/10; H10B 43/35; H10B 43/40; H10B 80/00

(52) U.S. Cl. CPC H10B 43/27; H01L 23/5226; H01L 23/5283; H01L 24/08; H01L 24/48; H01L 24/73; H01L 25/0652; H10B 41/10; H10B 41/27; H10B 41/35; H10B 41/40; H10B 43/10; H10B 43/35; H10B 43/40; H10B 80/00; H01L 2224/08145; H01L 2224/32225; H01L 2225/06506; H01L 2225/0651; H01L 2225/06524; H01L 2924/1431

(57) ABSTRACT

A three-dimensional semiconductor memory device may include a substrate, a peripheral circuit structure on the substrate, and a cell array structure on the peripheral circuit structure. The cell array structure may include a stack that includes interlayer insulating layers and conductive patterns alternately stacked with one another, a source structure on the stack, and a vertical structure that extends in the stack and is electrically connected to a bottom surface of the source structure. The vertical structure may include a channel layer that includes first portions respectively in vertical channel holes extending in the stack, and a second portion that extends in a region between the stack and the source structure and is electrically connected to the first portions.

### CROSS-REFERENCE TO RELATED APPLICATIONS

This U.S. non-provisional patent application claims priority under 35 U.S.C. § 119 to Korean Patent Application No. 10-2022-0119510, filed on Sep. 21, 2022, in the Korean Intellectual Property Office, the entire contents of which are hereby incorporated by reference.

### BACKGROUND

The present disclosure relates to a three-dimensional semiconductor memory device, a method of fabricating the same, and an electronic system including the same, and in particular, to a three-dimensional semiconductor memory device, which includes a peripheral circuit structure and a cell array structure connected to each other through bonding pads, a method of fabricating the same, and an electronic system including the same.

A semiconductor device capable of storing a large amount of data may be needed for data storage of an electronic system. In recent years, higher integration of semiconductor devices has advanced to satisfy consumer demands for large data storing capacity, superior performance, and inexpensive prices. In the case of two-dimensional or planar semiconductor devices, since integration is mainly determined by the area occupied by a unit memory cell, integration is greatly influenced by the level of a fine pattern forming technology. However, process equipment needed to increase pattern fineness can be increasingly expensive, which sets a practical limitation on increasing integration for two-dimensional or planar semiconductor devices. Thus, three-dimensional semiconductor memory devices including three-dimensionally arranged memory cells have recently been proposed.

### SUMMARY

Aspects of the inventive concept provide a three-dimensional semiconductor memory device with improved electrical characteristics and a method of fabricating the same.

Aspects of the inventive concept provide a three-dimensional semiconductor memory device and a simplified method of fabricating the same.

According to some embodiments of the inventive concept, a three-dimensional semiconductor memory device may include a substrate, a peripheral circuit structure on the substrate, and a cell array structure on the peripheral circuit structure. The cell array structure may include a stack that includes interlayer insulating layers and conductive patterns alternately stacked with one another, a source structure on the stack, and a vertical structure that extends in the stack and is electrically connected to a bottom surface of the source structure. The vertical structure may include a channel layer that includes first portions respectively in vertical channel holes extending in the stack, and a second portion that extends into a region between the stack and the source structure and is electrically connected to the first portions.

According to some embodiments of the inventive concept, a three-dimensional semiconductor memory device may include a substrate, a peripheral circuit structure on the substrate, and a cell array structure on the peripheral circuit structure. The cell array structure may include a cell array region, a cell array contact region, a stack that includes interlayer insulating layers and conductive patterns alternately stacked with one another, a source structure on the stack, a vertical structure that extends in the stack and is electrically connected to a bottom surface of the source structure, cell contact plugs in the cell array contact region and electrically connected to the conductive patterns, respectively, a source contact plug in the cell array contact region and electrically connected to the bottom surface of the source structure, and bit lines electrically connected to the cell contact plugs. The vertical structure may include a channel layer that includes first portions respectively in vertical channel holes extending in the stack, and a second portion that extends into a region between the stack and the source structure and is electrically connected to the first portions.

According to some embodiments of the inventive concept, an electronic system may include a three-dimensional semiconductor memory device that includes a substrate, a peripheral circuit structure on the substrate, and a cell array structure on the peripheral circuit structure, the cell array structuring including a cell array region and a cell array contact region, and a controller electrically connected to the three-dimensional semiconductor memory device through an input/output pad and configured to control the three-dimensional semiconductor memory device. The cell array structure may further include a stack that includes interlayer insulating layers and conductive patterns alternately stacked with one another, a source structure on the stack, and a vertical structure that extends in the stack and is electrically connected to a bottom surface of the source structure. The vertical structure may include a channel layer that includes first portions respectively in vertical channel holes extending in the stack, and a second portion that extends in a region between the stack and the source structure and is electrically connected to the first portions.

According to some embodiments of the inventive concept, a method of fabricating a three-dimensional semiconductor memory device may include forming preliminary vertical structures extending in a stack on a substrate, the preliminary vertical structures including data storage patterns and sacrificial patterns in vertical channel holes, respectively, removing the substrate to expose upper portions of the preliminary vertical structures, etching upper portions of the data storage patterns to expose the sacrificial patterns, removing the sacrificial patterns, forming a channel layer on a top surface of the stack and extending in the vertical channel holes, forming gap-fill insulating patterns in the vertical channel holes, respectively, and forming a source structure on the channel layer.

### BRIEF DESCRIPTION OF THE DRAWINGS

FIG. 1 is a diagram schematically illustrating an electronic system including a three-dimensional semiconductor memory device according to some embodiments of the inventive concept.

FIG. 2 is a perspective view schematically illustrating an electronic system including a three-dimensional semiconductor memory device according to some embodiments of the inventive concept.

FIGS. 3 and 4 are sectional views, which are respectively taken along lines I-I′ and II-II′ of FIG. 2 to illustrate a semiconductor package including a three-dimensional semiconductor memory device according to some embodiments of the inventive concept.

FIG. 5 is a plan view illustrating a three-dimensional semiconductor memory device according to some embodiments of the inventive concept.

FIGS. 6A and 6B are sectional views, which are respectively taken along lines I-I′ and II-II′ of FIG. 5 to illustrate a three-dimensional semiconductor memory device according to some embodiments of the inventive concept.

FIG. 7 is an enlarged sectional view illustrating a portion ‘Q’ of FIG. 6A.

FIGS. 8A, 11A, 12A, 13A, and 14A are sectional views, which are taken along the line I-I′ of FIG. 5 to illustrate a method of fabricating a three-dimensional semiconductor memory device according to some embodiments of the inventive concept.

FIGS. 8B, 11B, 12B, 13B, and 14B are sectional views, which are taken along the line II-II′ of FIG. 5 to illustrate a method of fabricating a three-dimensional semiconductor memory device according to some embodiments of the inventive concept.

FIGS. 9A and 10A are sectional views, which are taken along a line III-III′ of FIG. 5 to illustrate a method of fabricating a three-dimensional semiconductor memory device according to some embodiments of the inventive concept.

FIGS. 9B and 10B are sectional views, which are taken along a line IV-IV′ of FIG. 5 to illustrate a method of fabricating a three-dimensional semiconductor memory device according to some embodiments of the inventive concept.

### DETAILED DESCRIPTION

Example embodiments of the inventive concepts will now be described more fully with reference to the accompanying drawings, in which example embodiments are shown.

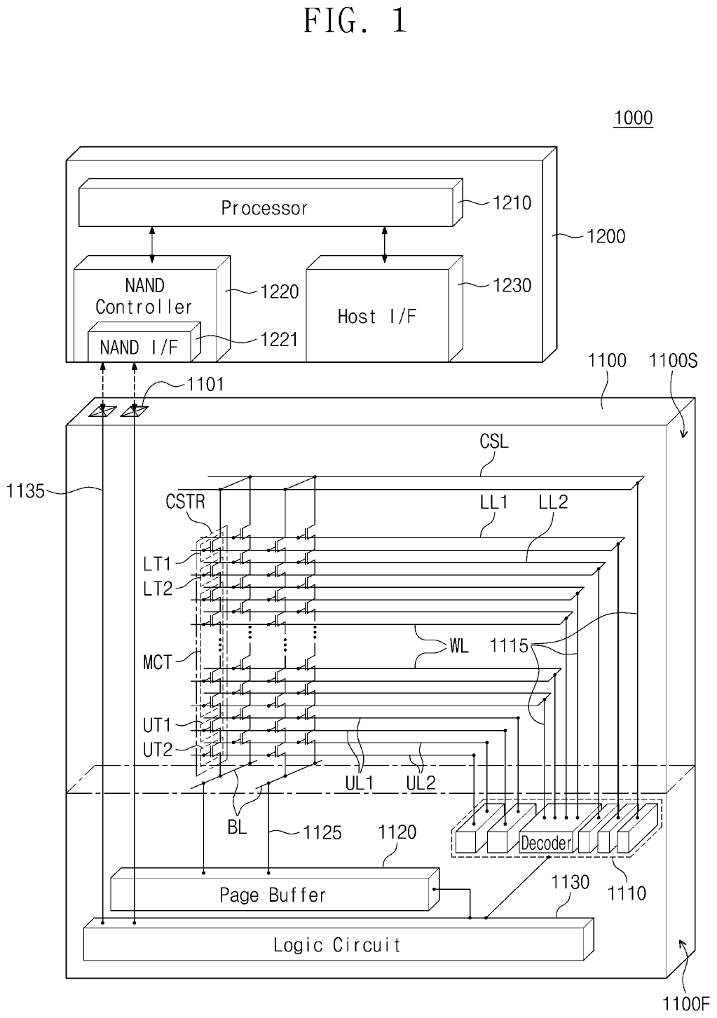

FIG. 1 is a diagram schematically illustrating an electronic system including a three-dimensional semiconductor memory device according to some embodiments of the inventive concept.

Referring to FIG. 1, an electronic system 1000 may include a three-dimensional semiconductor memory device 1100 and a controller 1200, which is electrically connected to the three-dimensional semiconductor memory device 1100. The electronic system 1000 may be a storage device including one or more three-dimensional semiconductor memory devices 1100 or an electronic device including the storage device. For example, the electronic system 1000 may be a solid state drive (SSD) device, a universal serial bus (USB), a computing system, a medical system, or a communication system, in which at least one three-dimensional semiconductor memory device 1100 is provided.

The three-dimensional semiconductor memory device 1100 may be a nonvolatile memory device (e.g., a three-dimensional NAND FLASH memory device to be described below). The three-dimensional semiconductor memory device 1100 may include a first region 1100F and a second region 1100S on the first region 1100F. However, unlike that illustrated in the drawings, in some embodiments, the first region 1100F may be disposed beside the second region 1100S. The first region 1100F may be a peripheral circuit region, which includes a decoder circuit 1110, a page buffer 1120, and a logic circuit 1130. The second region 1100S may be a memory cell region, which includes bit lines BL, a common source line CSL, word lines WL, first lines LL1 and LL2, second lines UL1 and UL2, and memory cell strings CSTR between the bit lines BL and the common source line CSL.

In the second region 1100S, each of the memory cell strings CSTR may include first transistors LT1 and LT2 adjacent to the common source line CSL, second transistors UT1 and UT2 adjacent to the bit lines BL, and a plurality of memory cell transistors MCT disposed between the first transistors LT1 and LT2 and the second transistors UT1 and UT2. The number of the first transistors LT1 and LT2 and the number of the second transistors UT1 and UT2 may be variously changed, according to embodiments. The memory cell strings CSTR may be positioned between the common source line CSL and the first region 1100F.

For example, the second transistors UT1 and UT2 may include a string selection transistor, and the first transistors LT1 and LT2 may include a ground selection transistor. The first lines LL1 and LL2 may serve as gate electrodes of the first transistors LT1 and LT2. The word lines WL may serve as gate electrodes of the memory cell transistors MCT, and the second lines UL1 and UL2 may serve as gate electrodes of the second transistors UT1 and UT2.

For example, the first transistors LT1 and LT2 may include a first erase control transistor LT1 and a ground selection transistor LT2, which are connected in series. For example, the second transistors UT1 and UT2 may include a string selection transistor UT1 and a second erase control transistor UT2, which are connected in series. At least one of the first and second erase control transistors LT1 and UT2 may be used for an erase operation of erasing data, which are stored in the memory cell transistors MCT, using a gate-induced drain leakage (GIDL) phenomenon.

The common source line CSL, the first lines LL1 and LL2, the word lines WL, and the second lines UL1 and UL2 may be electrically connected to the decoder circuit 1110 through first interconnection lines 1115, which are extended from the first region 1100F to the second region 1100S. The bit lines BL may be electrically connected to the page buffer 1120 through second interconnection lines 1125, which are extended from the first region 1100F to the second region 1100S.

In the first region 1100F, the decoder circuit 1110 and the page buffer 1120 may be configured to perform a control operation, which is performed on at least one memory cell transistor that is selected from the memory cell transistors MCT. The decoder circuit 1110 and the page buffer 1120 may be controlled by the logic circuit 1130. The three-dimensional semiconductor memory device 1100 may communicate with the controller 1200 through an input/output pad 1101, which is electrically connected to the logic circuit 1130. The input/output pad 1101 may be electrically connected to the logic circuit 1130 through an input/output interconnection line 1135, which is extended from the first region 1100F to the second region 1100S.

The controller 1200 may include a processor 1210, a NAND controller 1220, and a host interface 1230. In some embodiments, the electronic system 1000 may include a plurality of three-dimensional semiconductor memory devices 1100, which are controlled by the controller 1200.

The processor 1210 may control overall operations of the electronic system 1000 including the controller 1200. Based on a specific firmware, the processor 1210 may execute operations of controlling the NAND controller 1220 and accessing the three-dimensional semiconductor memory device 1100. The NAND controller 1220 may include a NAND interface 1221, which is used for communication with the three-dimensional semiconductor memory device 1100. The NAND interface 1221 may be used to transmit and receive control commands to control the three-dimensional semiconductor memory device 1100, data to be written in or read from the memory cell transistors MCT of the three-dimensional semiconductor memory device 1100, and so forth. The host interface 1230 may be configured to allow for communication between the electronic system 1000 and an external host. If a control command is provided from an external host through the host interface 1230, the processor 1210 may control the three-dimensional semiconductor memory device 1100 in response to the control command.

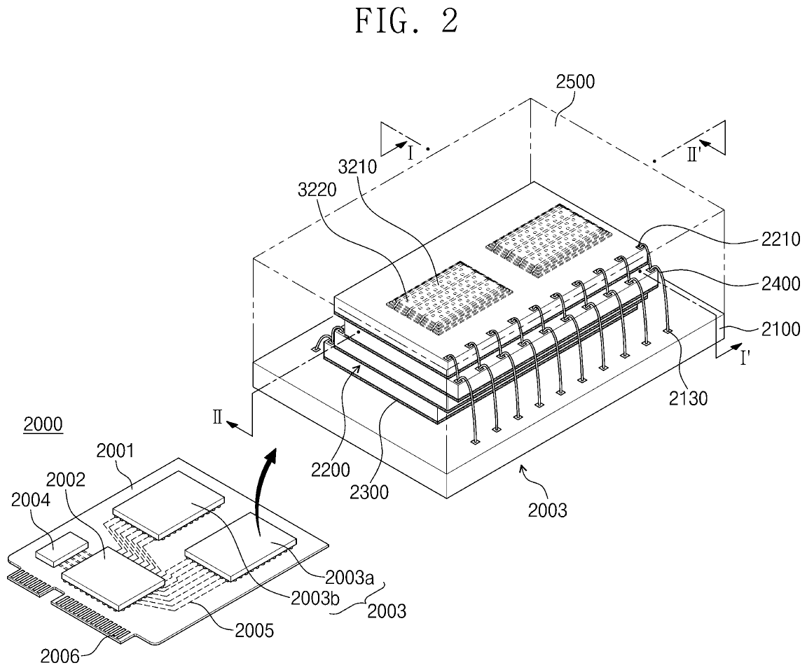

FIG. 2 is a perspective view schematically illustrating an electronic system including a three-dimensional semiconductor memory device according to some embodiments of the inventive concept.

Referring to FIG. 2, an electronic system 2000 may include a main substrate 2001 and a controller 2002, one or more semiconductor packages 2003, and a DRAM 2004, which are mounted on the main substrate 2001. The semiconductor package 2003 and the DRAM 2004 may be connected to the controller 2002 and to each other by interconnection patterns 2005, which are provided in the main substrate 2001.

The main substrate 2001 may include a connector 2006, which includes a plurality of pins coupled to an external host. In the connector 2006, the number and the arrangement of the pins may be changed depending on a communication interface between the electronic system 2000 and an external host. For example, the electronic system 2000 may communicate with the external host, in accordance with one of interfaces, such as universal serial bus (USB), peripheral component interconnect express (PCI-Express), serial advanced technology attachment (SATA), universal flash storage (UFS) M-PHY, or the like. In some embodiments, the electronic system 2000 may be driven by an electric power, which is supplied from the external host through the connector 2006. The electronic system 2000 may further include a power management integrated circuit (PMIC) that is used to separately supply the electric power, which is provided from the external host, to the controller 2002 and the semiconductor package 2003.

The controller 2002 may control a writing or reading operation on the semiconductor package 2003 and may improve an operation speed of the electronic system 2000.

The DRAM 2004 may be a buffer memory that is used to relieve technical difficulties caused by a difference in speed between the semiconductor package 2003, which serves as a data storage device, and an external host. In some embodiments, the DRAM 2004 in the electronic system 2000 may serve as a cache memory and may be used as a storage space, which is used to temporarily store data during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b, which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200, which are provided on the package substrate 2100, adhesive layers 2300, which are respectively disposed in bottom surfaces of the semiconductor chips 2200, connection structures 2400, which are used to electrically connect the semiconductor chips 2200 to the package substrate 2100, and a molding layer 2500, which is provided on the package substrate 2100 to cover the semiconductor chips 2200 and the connection structures 2400.

The package substrate 2100 may be a printed circuit board including package upper pads 2130. Each of the semiconductor chips 2200 may include input/output pads 2210. Each of the input/output pads 2210 may correspond to the input/output pad 1101 of FIG. 1. Each of the semiconductor chips 2200 may include gate stacks 3210 and memory channel structures 3220. Each of the semiconductor chips 2200 may include a three-dimensional semiconductor memory device, which will be described below.

The connection structures 2400 may be, for example, bonding wires, which are used to electrically connect the input/output pads 2210 to the package upper pads 2130. That is, in each of the first and second semiconductor packages 2003a and 2003b, the semiconductor chips 2200 may be electrically connected to each other in a bonding wire manner and may be electrically connected to the package upper pads 2130 of the package substrate 2100.

Unlike that illustrated in FIG. 2, the controller 2002 and the semiconductor chips 2200 may be included in a single package. In some embodiments, the controller 2002 and the semiconductor chips 2200 may be mounted on a separate interposer substrate, not on the main substrate 2001, and may be connected to each other through interconnection lines, which are provided in the interposer substrate.

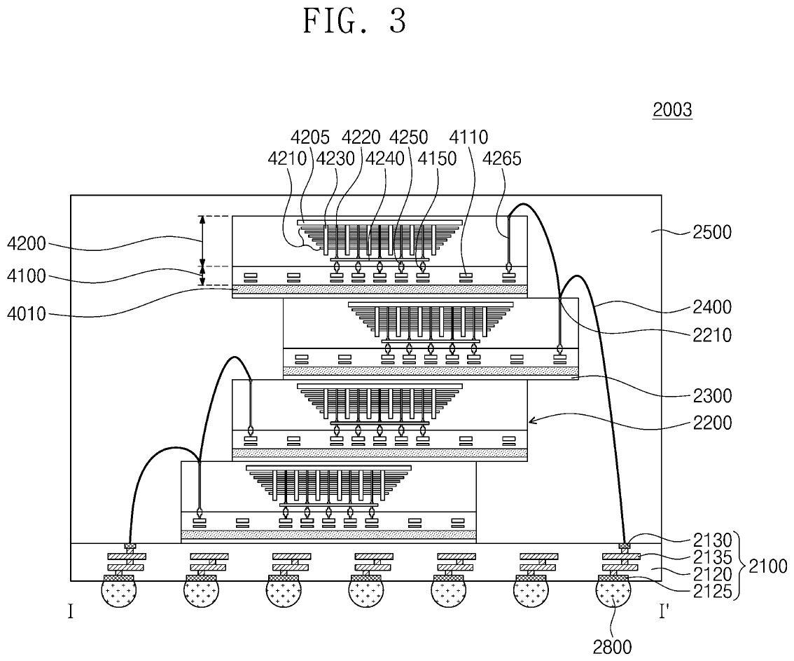

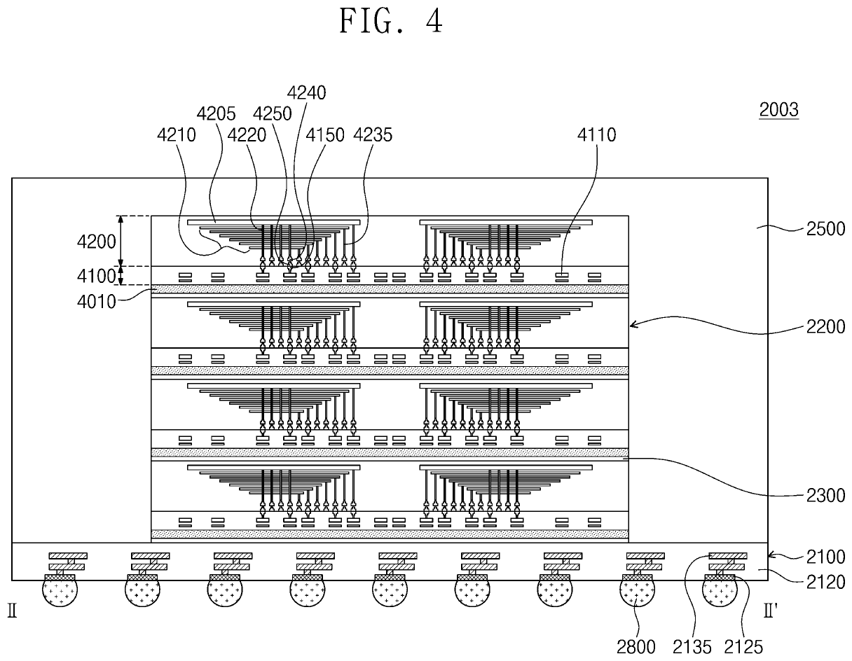

FIGS. 3 and 4 are sectional views, which are respectively taken along lines I-I′ and II-II′ of FIG. 2 to illustrate a semiconductor package including a three-dimensional semiconductor memory device according to some embodiments of the inventive concept.

Referring to FIGS. 3 and 4, the semiconductor package 2003 may include the package substrate 2100, the semiconductor chips 2200 on the package substrate 2100, and the molding layer 2500 covering the package substrate 2100 and the semiconductor chips 2200.

The package substrate 2100 may include a package substrate body portion 2120, upper pads 2130, which are provided on a top surface of the package substrate body portion 2120 and are exposed to the outside of the package substrate body portion 2120 near the top surface, lower pads 2125, which are provided on a bottom surface of the package substrate body portion 2120 or are exposed to the outside of the package substrate body portion 2120 near the bottom surface, and internal lines 2135, which are provided in the package substrate body portion 2120 to electrically connect the upper pads 2130 to the lower pads 2125. The upper pads 2130 may be electrically connected to the connection structures 2400. The lower pads 2125 may be connected to the interconnection patterns 2005 of the main substrate 2001 of the electronic system 2000, which is shown in FIG. 2, through conductive connecting portions 2800.

Referring to FIGS. 2 and 3, the semiconductor chips 2200 may be provided to have side surfaces, which are not aligned to each other, and other side surfaces, which are aligned to each other. The semiconductor chips 2200 may be electrically connected to each other through the connection structures 2400, which are provided in the form of bonding wires. Each of the semiconductor chips 2200 may include substantially the same elements. Alternatively, as shown in FIG. 4, the semiconductor chips 2200 may be electrically connected to each other by penetration electrodes (e.g., through-silicon vias (TSVs)), not by the bonding wire method using the connection structures 2400.

Each of the semiconductor chips 2200 may include a semiconductor substrate 4010, a first structure 4100 on the semiconductor substrate 4010, and a second structure 4200 on the first structure 4100. The second structure 4200 may be connected to the first structure 4100 in a wafer bonding manner.

The first structure 4100 may include peripheral circuit interconnection lines 4110 and first bonding pads 4150. The second structure 4200 may include a common source line 4205, a gate stack 4210, which is provided between the common source line 4205 and the first structure 4100, memory channel structures 4220 and separation structures 4230, which are provided to penetrate or extend in the gate stack 4210, and second bonding pads 4250, which are electrically and respectively connected to the memory channel structures 4220 and the word lines WL (e.g., see FIG. 1) of the gate stack 4210. For example, the second bonding pads 4250 may be electrically and respectively connected to the memory channel structures 4220 and the word lines WL through bit lines 4240, which are electrically connected to the memory channel structures 4220, and gate interconnection lines 4235, which are electrically connected to the word lines WL. The first bonding pads 4150 of the first structure 4100 and the second bonding pads 4250 of the second structure 4200 may be in contact with each other and may be coupled to each other. The coupling portions between the first bonding pads 4150 and the second bonding pads 4250 may be formed of or include, for example, copper (Cu).

Each of the semiconductor chips 2200 may further include the input/output pad 2210 and an input/output interconnection line 4265 below the input/output pad 2210. The input/output interconnection line 4265 may be electrically connected to some of the second bonding pads 4250 and some of the peripheral circuit interconnection lines 4110.

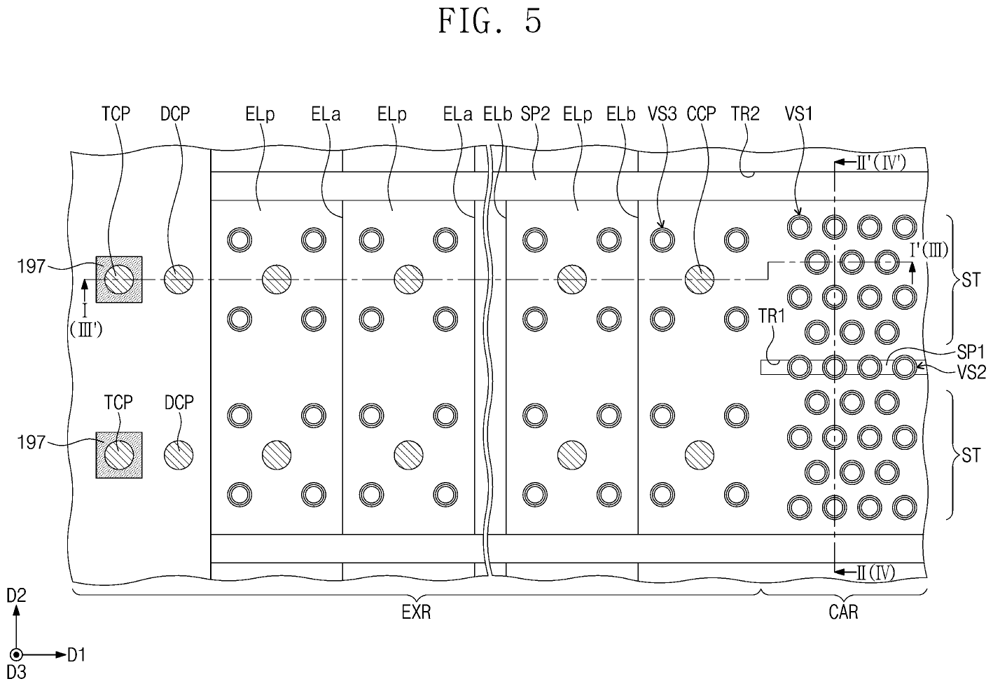

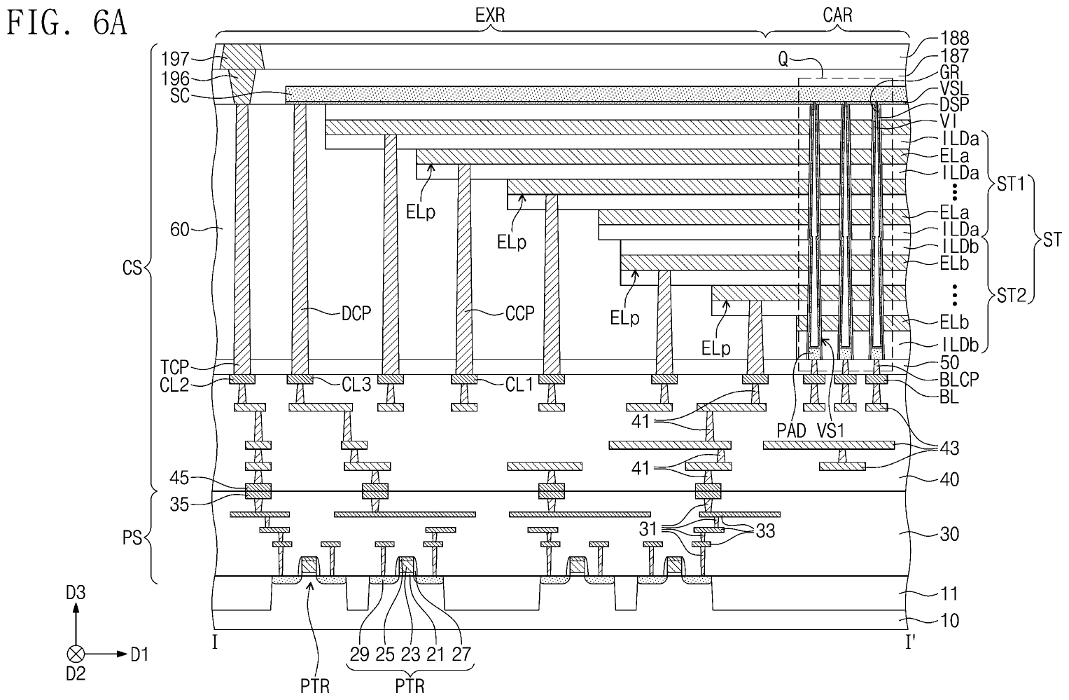

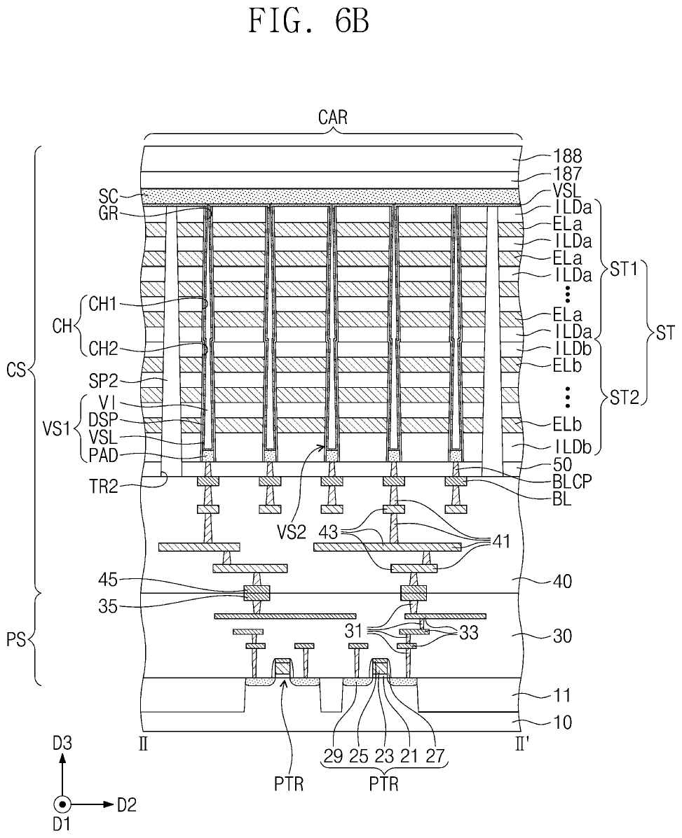

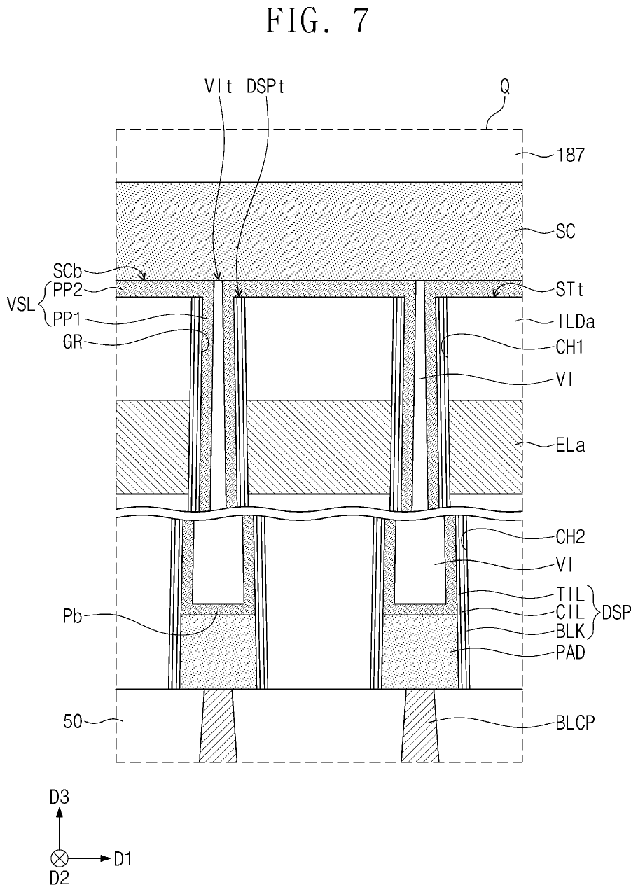

FIG. 5 is a plan view illustrating a three-dimensional semiconductor memory device according to some embodiments of the inventive concept. FIGS. 6A and 6B are sectional views, which are respectively taken along lines I-I′ and II-IF of FIG. 5 to illustrate a three-dimensional semiconductor memory device according to some embodiments of the inventive concept. FIG. 7 is an enlarged sectional view illustrating a portion ‘Q’ of FIG. 6A.

Referring to FIGS. 5, 6A, and 6B, a three-dimensional semiconductor memory device according to some embodiments of the inventive concept may include a substrate 10, a peripheral circuit structure PS on the substrate 10, and a cell array structure CS on the peripheral circuit structure PS. The substrate 10, the peripheral circuit structure PS, and the cell array structure CS may correspond to the semiconductor substrate 4010, the first structure 4100 on the semiconductor substrate 4010, and the second structure 4200 on the first structure 4100, respectively, described with reference to FIGS. 3 and 4. Hereinafter, the substrate 10 and the peripheral circuit structure PS will be described as separate elements, but in some embodiments, the substrate 10 may be a part of the peripheral circuit structure PS or the substrate 10 and the peripheral circuit structure PS may be parts of the same semiconductor chip.

Since the peripheral circuit structure PS is coupled to the cell array structure CS thereon, the three-dimensional semiconductor memory device may have an increased cell capacity per unit area. In addition, the peripheral circuit structure PS and the cell array structure CS may be separately fabricated and then may be coupled to each other, and in this case, it may be possible to prevent peripheral transistors PTR from being damaged by several thermal treatment processes. Accordingly, the electrical and reliability characteristics of the three-dimensional semiconductor memory device may be improved.

In some embodiments, the substrate 10 may be a silicon substrate, a silicon-germanium substrate, a germanium substrate, or a structure including a single-crystalline silicon substrate and a single-crystalline epitaxial layer grown therefrom. The substrate 10 may have a top surface that is parallel to two different directions (e.g., a first direction D1 and a second direction D2) and is perpendicular to a third direction D3. For example, the first to third directions D1, D2, and D3 may be orthogonal to each other. A device isolation layer 11 may be provided in the substrate 10. The device isolation layer 11 may define an active region of the substrate 10.

The peripheral circuit structure PS may be provided on the substrate 10, and in some embodiments, the peripheral circuit structure PS may include the peripheral transistors PTR, peripheral contact plugs 31, peripheral circuit interconnection lines 33 electrically connected to the peripheral transistors PTR through the peripheral contact plugs 31, first bonding pads 35 electrically connected to the peripheral circuit interconnection lines 33, and a first interlayer insulating layer 30 enclosing them. The peripheral transistors PTR may be provided on the active region of the substrate 10. The peripheral circuit interconnection lines 33 may correspond to the peripheral circuit interconnection lines 4110 of FIGS. 3 and 4, and the first bonding pads 35 may correspond to the first bonding pads 4150 of FIGS. 3 and 4.

In some embodiments, widths of the peripheral contact plugs 31 measured in the first or second direction D1 or D2 may increase as a distance in the third direction D3 increases. For example, in some embodiments, widths of the peripheral contact plugs 31 in the first or second direction D1 or D2 may increase as a distance from the substrate 10 increases in the third direction D3. The peripheral contact plugs 31 and the peripheral circuit interconnection lines 33 may be formed of or include at least one conductive material (e.g., metallic materials).

In some embodiments, the peripheral transistors PTR may constitute at least one of the decoder circuit 1110, the page buffer 1120, or the logic circuit 1130 of FIG. 1. More specifically, each of the peripheral transistors PTR may include a peripheral gate insulating layer 21, a peripheral gate electrode 23, a peripheral capping pattern 25, a peripheral gate spacer 27, and peripheral source/drain regions 29. The peripheral gate insulating layer 21 may be provided between the peripheral gate electrode 23 and the substrate 10. The peripheral capping pattern 25 may be provided on the peripheral gate electrode 23. The peripheral gate spacer 27 may be provided to cover side surfaces of the peripheral gate insulating layer 21, the peripheral gate electrode 23, and the peripheral capping pattern 25. The peripheral source/drain regions 29 may be provided in portions of the substrate 10, which are located at both sides of the peripheral gate electrode 23. The peripheral circuit interconnection lines 33 and the first bonding pads 35 may be electrically connected to the peripheral transistors PTR through the peripheral contact plugs 31. Each of the peripheral transistors PTR may be, for example, an NMOS transistor or a PMOS transistor.

The first interlayer insulating layer 30 may be provided on the substrate 10. The first interlayer insulating layer 30 may cover or be on the peripheral transistors PTR, the peripheral contact plugs 31, and the peripheral circuit interconnection lines 33, on the substrate 10. The first interlayer insulating layer 30 may be provided to include a single insulating layer or a plurality of insulating layers having a multi-layered structure. In some embodiments, the first interlayer insulating layer 30 may be formed of or include at least one of silicon oxide, silicon nitride, silicon oxynitride, and/or low-k dielectric materials. The first interlayer insulating layer 30 may not cover or be on top surfaces of the first bonding pads 35. The first interlayer insulating layer 30 may have a top surface that is substantially coplanar with the top surfaces of the first bonding pads 35.

The cell array structure CS may be provided on the peripheral circuit structure PS, and in some embodiments, the cell array structure CS may include second bonding pads 45, the bit lines BL, a stack ST, and a source structure SC. The cell array structure CS may include a cell array region CAR and a cell array contact region EXR. The cell array contact region EXR may be extended from the cell array region CAR in the first direction D1 on a left or right side thereof.

The second bonding pads 45, the bit lines BL, and the stack ST may correspond to the second bonding pads 4250, the bit lines 4240, and the gate stack 4210, respectively, described with reference to FIGS. 3 and 4. A second interlayer insulating layer 40, connection contact plugs 41, connection circuit interconnection lines 43, and the second bonding pads 45 may be provided on the first interlayer insulating layer 30. Here, the second bonding pads 45 may be provided to be in contact with the first bonding pads 35 of the peripheral circuit structure PS, the connection circuit interconnection lines 43 may be electrically connected to the second bonding pads 45 through the connection contact plugs 41, and the second interlayer insulating layer 40 may be provided to enclose the connection contact plugs 41, the connection circuit interconnection lines 43, and the second bonding pads 45.

The second interlayer insulating layer 40 may have a single layer structure or a multi-layered structure including a plurality of insulating layers. In some embodiments, the second interlayer insulating layer 40 may be formed of or include at least one of silicon oxide, silicon nitride, silicon oxynitride, and/or low-k dielectric materials.

In some embodiments, widths of the connection contact plugs 41 measured in the first or second direction D1 or D2 may decrease as a distance in the third direction D3 increases. For example, in some embodiments, widths of the connection contact plugs 41 in the first or second direction D1 or D2 may decrease as a distance from the substrate 10 increases in the third direction D3. The connection contact plugs 41 and the connection circuit interconnection lines 43 may be formed of or include at least one conductive material (e.g., metallic materials).

The second interlayer insulating layer 40 may not cover or be on bottom surfaces of the second bonding pads 45. A bottom surface of the second interlayer insulating layer 40 may be substantially coplanar with the bottom surfaces of the second bonding pads 45. The bottom surface of each of the second bonding pads 45 may be in direct contact with the top surface of a corresponding one of the first bonding pads 35. The first and second bonding pads 35 and 45 may be formed of or include at least one metallic material (e.g., copper (Cu), tungsten (W), aluminum (Al), nickel (Ni), or tin (Sn)). For example, the first and second bonding pads 35 and 45 may be formed of or include copper (Cu). The first and second bonding pads 35 and 45 may be connected to each other without any interface therebetween and may form a single object. The side surfaces of the first and second bonding pads 35 and 45 are illustrated to be aligned to each other, but the inventive concept is not limited to this example. For example, the side surfaces of the first and second bonding pads 35 and 45 may be spaced apart from each other in the first or second direction D1 or D2, when viewed in a plan view.

The bit lines BL and first to third conductive lines CL1, CL2, and CL3, which are in contact with the connection contact plugs 41, may be provided in an upper portion of the second interlayer insulating layer 40. In some embodiments, the bit lines BL and the first to third conductive lines CL1, CL2, and CL3 may be extended in the second direction D2 and may be spaced apart from each other in the first direction D1. The bit lines BL and the first to third conductive lines CL1, CL2, and CL3 may be formed of or include at least one conductive material (e.g., metallic materials).

A third interlayer insulating layer 50 may be provided on the second interlayer insulating layer 40. A fourth interlayer insulating layer 60 and the stack ST may be provided on the third interlayer insulating layer 50, and here, the stack ST may be enclosed by the fourth interlayer insulating layer 60. The third and fourth interlayer insulating layers 50 and 60 may be a single layer structure or a multi-layered structure including a plurality of insulating layers. In some embodiments, the third and fourth interlayer insulating layers 50 and 60 may be formed of or include at least one of silicon oxide, silicon nitride, silicon oxynitride, and/or low-k dielectric materials.

Bit line contact plugs BLCP may be provided in the third interlayer insulating layer 50. The bit line contact plugs BLCP may be extended in the third direction D3 to connect the bit lines BL to first vertical structures VS1, which will be described below.

Cell contact plugs CCP, a source contact plug DCP, and a penetration contact plug TCP may be provided to penetrate or extend in the third interlayer insulating layer 50 and the fourth interlayer insulating layer 60. The cell contact plugs CCP may be extended in the third direction D3 to connect the first conductive lines CL1 to gate electrodes ELa and ELb of the stack ST, which will be described below. Each of the cell contact plugs CCP may be provided to penetrate or extend in one of interlayer insulating layers ILDa and ILDb of the stack ST, which will be described below. The penetration contact plug TCP may be extended in the third direction D3 to connect the second conductive line CL2 to a back-side conductive pattern 197, which will be described below. The source contact plug DCP may be extended in the third direction D3 to connect a source structure SC, which will be described below, to the third conductive line CL3.

The bit line contact plugs BLCP, the cell contact plugs CCP, the source contact plug DCP, and the penetration contact plug TCP may be spaced apart from each other in the first direction D1. Widths of the bit line contact plugs BLCP, the cell contact plugs CCP, the source contact plug DCP, and the penetration contact plug TCP, which are measured in the first and/or second directions D1 and/or D2, may decrease as a distance from the substrate 10 in the third direction D3 increases. The bit line contact plugs BLCP, the cell contact plugs CCP, the source contact plug DCP, and the penetration contact plug TCP may be formed of or include at least one metallic material (e.g., tungsten). A bottom surface of the stack ST (i.e., in contact with the third interlayer insulating layer 50) may be substantially coplanar with a bottom surface of the fourth interlayer insulating layer 60.

In some embodiments, a plurality of the stacks ST may be provided. The stacks ST may be extended in the first direction D1 and may be spaced apart from each other in the second direction D2, when viewed in the plan view of FIG. 5. Hereinafter, just one stack ST will be described, for brevity's sake, but the others of the stacks ST may also have substantially the same features as described below.

The stack ST may include interlayer insulating layers and conductive patterns, which are alternately and repeatedly disposed or stacked with one another. The stack ST may have an inverted staircase structure or stepped structure which is composed of the interlayer insulating layers and the conductive patterns. As an example, the stack ST may include a first stack ST1 and a second stack ST2. The first stack ST1 may include first interlayer insulating layers ILDa and first gate electrodes ELa, which are alternately stacked with one another, and the second stack ST2 may include second interlayer insulating layers ILDb and second gate electrodes ELb, which are alternately stacked with one another.

The second stack ST2 may be provided between the first stack ST1 and the substrate 10. More specifically, the second stack ST2 may be provided on a bottom surface of the bottommost or lowermost one of the first interlayer insulating layers ILDa of the first stack ST1. The topmost or uppermost one of the second interlayer insulating layers ILDb of the second stack ST2 may be in contact with the bottommost or lowermost one of the first interlayer insulating layers ILDa of the first stack ST1, but the inventive concept is not limited to this example. For example, a single insulating layer may be provided between the topmost or uppermost one of the second gate electrodes ELb of the second stack ST2 and the lowermost one of the first gate electrodes ELa of the first stack ST1.

The first and second gate electrodes ELa and ELb may be formed of or include at least one of, for example, doped semiconductor materials (e.g., doped silicon and so forth), metallic materials (e.g., tungsten, molybdenum, nickel, copper, aluminum, and so forth), conductive metal nitrides (e.g., titanium nitride, tantalum nitride, and so forth), or transition metals (e.g., titanium, tantalum, and so forth). The first and second interlayer insulating layers ILDa and ILDb may be formed of or include at least one of silicon oxide, silicon nitride, silicon oxynitride, and/or low-k dielectric materials. For example, the first and second interlayer insulating layers ILDa and ILDb may be formed of or include high density plasma (HDP) oxide or tetraethyl orthosilicate (TEOS).

On the cell array contact region EXR, a thickness of each of the first and second stacks ST1 and ST2 in the third direction D3 may decrease as a distance from the outermost one of first vertical structures VS1 to be described below increases. In other words, each of the first and second stacks ST1 and ST2 may have a staircase structure or stepped structure, which is inverted in the first direction D1.

More specifically, lengths of the first and second gate electrodes ELa and ELb in the first direction D1 may increase as a distance from the substrate 10 increases in the third direction D3. Side surfaces of the first and second gate electrodes ELa and ELb may be spaced apart from each other by a specific distance in the first direction D1, when viewed in the plan view of FIG. 5. The lowermost one of the second gate electrodes ELb of the second stack ST2 may have the shortest length in the first direction D1, and the uppermost one of the first gate electrodes ELa of the first stack ST1 may have the longest length in the first direction D1.

The first and second gate electrodes ELa and ELb may include pad portions ELp, which are provided on the cell array contact region EXR. The pad portions ELp may be disposed at positions that are different from each other in horizontal and vertical directions. The pad portions ELp may be provided to form a staircase structure or stepped structure in the first direction D1. Each of the cell contact plugs CCP may penetrate or extend in a corresponding one of the first and second interlayer insulating layers ILDa and ILDb and may be in contact with the pad portion ELp of a corresponding one of the first and second gate electrodes ELa and ELb. The source contact plug DCP may be provided to penetrate or extend in the fourth interlayer insulating layer 60 and to be in contact with a source structure SC.

Each of the first and second interlayer dielectric layers ILDa and ILDb may be provided between a corresponding pair of the first and second gate electrodes ELa and ELb and may have a side surface that is aligned to a side surface of a corresponding one of the first and second gate electrodes ELa and ELb, which are in contact with an upper portion thereof. The lowermost one of the second interlayer insulating layers ILDb may have a thickness larger or greater than the others in the third direction D3, but the inventive concept is not limited to this example.

A vertical structure may be provided in the cell array region CAR to penetrate or extend in the stack ST in the third direction D3. The vertical structure may include first vertical structures VS1 and second vertical structures VS2, which are provided in vertical channel holes CH. The first vertical structures VS1 may correspond to the memory channel structures 4220 of FIGS. 3 and 4.

In the cell array contact region EXR, third vertical structures VS3 may be provided in the vertical channel holes CH, which are formed to penetrate or extend in at least a portion of the stack ST and the fourth interlayer insulating layer 60 in the third direction D3. As shown in FIG. 5, a plurality of third vertical structures VS3 may be provided around each of the cell contact plugs CCP.

The vertical channel holes CH may include first vertical channel holes CH1 and second vertical channel holes CH2, which are connected to the first vertical channel holes CH1. Widths of the first and second vertical channel holes CH1 and CH2 measured in the first or second direction D1 or D2 may decrease with increasing distance from the substrate 10 in the third direction D3. The first and second vertical channel holes CH1 and CH2 may have diameters different from each other near a boundary region where the first and second vertical channel holes CH1 and CH2 are connected to each other. In detail, an upper diameter of each of the second vertical channel holes CH2 may be smaller than a lower diameter of each of the first vertical channel holes CH1. The first and second vertical channel holes CH1 and CH2 may form a stepwise structure near the boundary region. However, the inventive concept is not limited to this example, and in some embodiments, the first to third vertical structures VS1, VS2, and VS3 may be provided in three or more vertical channel holes CH, which are provided to form stepwise structures at two or more different levels, or may be provided in vertical channel holes CH whose side surfaces are substantially flat without such a stepwise structure.

As shown in FIGS. 6B and 7, each of the first to third vertical structures VS1, VS2, and VS3 may include a conductive pad PAD, which is adjacent to or on the third interlayer insulating layer 50, a data storage pattern DSP, which is provided to conformally cover or be on an inner side surface of each of the first and second vertical channel holes CH1 and CH2, a channel layer VSL, which is provided to conformally cover or be on a side surface of the data storage pattern DSP, and a gap-fill insulating pattern VI, which is provided to fill or be in an internal space of each of the first and second vertical channel holes CH1 and CH2 enclosed by the channel layer VSL and the conductive pad PAD. For example, the conductive pads PAD may respectively be in lower portions of the vertical channel holes CH (e.g., lower portions of the second vertical channel holes CH2) In some embodiments, a bottom surface of each of the first to third vertical structures VS1, VS2, and VS3 may have a circular, elliptical, or bar shape. The gap-fill insulating pattern VI may be formed of or include silicon oxide.

The channel layer VSL may include first portions PP1 and a second portion PP2. The first portions PP1 may be provided in the vertical channel holes CH, which are formed to penetrate or extend in the stack ST. The second portions PP2 may be extended into a space between the stack ST and the source structure SC and may be connected in common to the first portions PP1. In detail, the first portions PP1 may be provided in the vertical channel holes CH, respectively, and may be provided in a gap region GR, which is defined by an inner surface of the data storage pattern DSP, and the second portion PP2 may be a portion of the channel layer, which is extended from the first portions PP1. The first portions PP1 may be extended along top surfaces of the conductive pads PAD. For example, lower portions of the first portions PP1 may respectively extend along top surfaces of the conductive pads PAD. That is, the first portions PP1 may be extended into regions between the conductive pads PAD and the gap-fill insulating patterns VI and may be shaped like a pipe with closed bottom Pb. For example, each of the first portions PP1 may have a closed end pipe shape in a cross-sectional view. For example, the closed end may be along a bottom surface of each of the first portions PP1 in a cross-sectional view. The first to third vertical structures VS1, VS2, and VS3 may be connected to each other by the second portion PP2.

The second portion PP2 may be extended into a region between a bottom surface SCb of the source structure SC and a top surface STt of the stack ST. As an example, a top surface of the second portion PP2 may be in contact with the bottom surface SCb of the source structure SC. A bottom surface of the second portion PP2 may cover or be on top surfaces DSPt of the data storage patterns DSP. The top surface of the second portion PP2 may be located at substantially the same level as top surfaces VIt of the gap-fill insulating patterns VI in the third direction D3, relative to the substrate 10. The top surfaces VIt of the gap-fill insulating patterns VI may be in contact with the bottom surface SCb of the source structure SC. The top surfaces VIt of the gap-fill insulating patterns VI may be located at a level higher than the top surface STt of the stack ST in the third direction D3, relative to the substrate 10. A thickness of the second portion PP2 in the third direction D3 may be smaller than a thickness of the source structure SC in the third direction D3. For example, a thickness of the second portion PP2 in the third direction D3 may be less than that of the source structure SC. When viewed in a plan view, the second portion PP2 may have a plate-shape pattern, which is extended in the first and second directions D1 and D2.

The source structure SC may be provided on the stack ST. The source structure SC may correspond to the common source line 4205 of FIGS. 3 and 4. An end portion of the source structure SC may be aligned to an end portion of the second portion PP2. The source structure SC may be formed of or include a semiconductor material. As an example, the source structure SC may be a polysilicon layer that is doped with n-type dopants.

The channel layer VSL may be formed of or include a material whose electron mobility is higher than that of polysilicon. The channel layer VSL may include a semiconductor layer, which is formed of a single element but not silicon, or a layer, which is formed of a compound semiconductor material. The channel layer VSL may be formed of or include a material that is different from the source structure SC. That is, the channel layer VSL may be formed of or include a non-silicon material. As an example, the channel layer VSL may be formed of or include at least one of group IV elements (e.g., SiGe or Ge), oxide semiconductor materials (e.g., zinc tin oxide (ZTO), amorphous or crystalline indium gallium zinc oxide (IGZO)), or group III-V elements (e.g., InAs or InGaAs). In the case where the channel layer VSL includes IGZO, at least a portion of the layer may have an amorphous structure.

When viewed in the plan view of FIG. 5, a first trench TR1 and a second trench TR2 may be provided to extend in the first direction D1 and to cross or intersect the stack ST. The first trench TR1 may be provided in the cell array region CAR, and the second trench TR2 may be extended from the cell array region CAR toward the cell array contact region EXR. A width of each of the first and second trenches TR1 and TR2 in the first or second direction D1 or D2 may decrease with increasing distance from the substrate 10 in the third direction D3.

A first separation pattern SP1 and a second separation pattern SP2 may be provided to fill or be in the first trench TR1 and the second trench TR2, respectively. The first and second separation patterns SP1 and SP2 may correspond to the separation structures 4230 of FIGS. 3 and 4. A length of the second separation pattern SP2 in the first direction D1 may be larger or greater than a length of the first separation pattern SP1 in the first direction D1. Side surfaces of the first and second separation patterns SP1 and SP2 may be in contact with at least a portion of the first and second gate electrodes ELa and ELb and the first and second interlayer insulating layers ILDa and ILDb of the stack ST. In some embodiments, the first and second separation patterns SP1 and SP2 may be formed of or include at least one oxide material (e.g., silicon oxide).

A bottom surface of the second separation pattern SP2 may be substantially coplanar with the bottom surface of the third interlayer insulating layer 50 (i.e., the top surface of the second interlayer insulating layer 40) and the top surfaces of the bit lines BL and the first and second conductive lines CL1 and CL2. A top surface of the second separation pattern SP2 may be located at a level that is lower in the third direction D3 than the top surfaces of the first to third vertical structures VS1, VS2, and VS3, relative to the substrate 10.

In the case where a plurality of the stacks ST are provided, the first separation pattern SP1 or the second separation pattern SP2 may be provided between the stacks ST that are arranged in the second direction D2. For example, the stacks ST may be spaced apart from each other in the second direction D2 with the first or second separation pattern SP1 or SP2 interposed therebetween.

A fifth interlayer insulating layer 187 and a sixth interlayer insulating layer 188 may be sequentially provided on the source structure SC. A penetration via 196, which is connected to the penetration contact plug TCP, may be provided in the fifth interlayer insulating layer 187. The back-side conductive pattern 197, which is connected to the penetration via 196, may be provided in the sixth interlayer insulating layer 188.

The data storage pattern DSP may include a blocking insulating layer BLK, a charge storing layer CIL, and a tunneling insulating layer TIL, which are sequentially stacked on an inner side surface of the vertical channel hole CH. The charge storing layer CIL may be interposed between the blocking insulating layer BLK and the tunneling insulating layer TIL. In some embodiments, the Fowler-Nordheim (FN) tunneling phenomenon, which is caused by a voltage difference between the channel layer VSL and the first and second gate electrodes ELa and ELb, may be used to store or change data in the data storage pattern DSP. In some embodiments, the blocking insulating layer BLK and the tunneling insulating layer TIL may be formed of or include silicon oxide, and the charge storing layer CIL may be formed of or include silicon nitride or silicon oxynitride.

The penetration via 196 may be provided to have a top surface whose width is larger or greater than that of a bottom surface thereof in the first or second direction D1 or D2. The back-side conductive pattern 197 may be provided on the penetration via 196. The back-side conductive pattern 197 may have a bottom surface, which has a width larger or greater than a width of a top surface thereof in the first or second direction D1 or D2. The back-side conductive pattern 197 may be electrically connected to the second conductive line CL2 through the penetration via 196 and the penetration contact plug TCP, and moreover, the back-side conductive pattern 197 may be electrically connected to at least one of the peripheral transistors PTR of the peripheral circuit structure PS. The back-side conductive pattern 197 may correspond to one of the input/output pad 1101 of FIG. 1 or the input/output pads 2210 of FIGS. 3 and 4. However, in some embodiments, the back-side conductive pattern 197 may be a back-side metal line. The back-side conductive pattern 197 may be formed of or include a material that is different from the penetration via 196 and the penetration contact plug TCP. In some embodiments, the back-side conductive pattern 197 may be formed of or include aluminum, and the penetration via 196 and the penetration contact plug TCP may be formed of or include at least one of tungsten, titanium, or tantalum.

According to some embodiments of the inventive concept, the channel layer VSL may be formed of or include a material whose electron mobility is higher than that of polysilicon. This may make it possible to improve electrical characteristics of the semiconductor memory device.

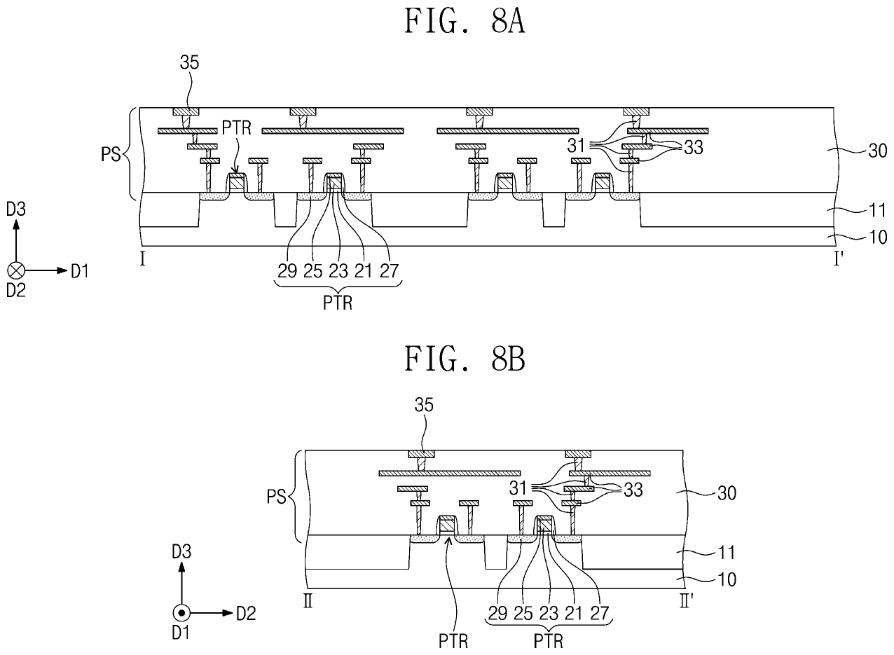

FIGS. 8A, 11A, 12A, 13A, and 14A are sectional views, which are taken along the line I-I′ of FIG. 5 to illustrate a method of fabricating a three-dimensional semiconductor memory device according to some embodiments of the inventive concept. FIGS. 8B, 11B, 12B, 13B, and 14B are sectional views, which are taken along the line II-IP of FIG. 5 to illustrate a method of fabricating a three-dimensional semiconductor memory device according to some embodiments of the inventive concept.

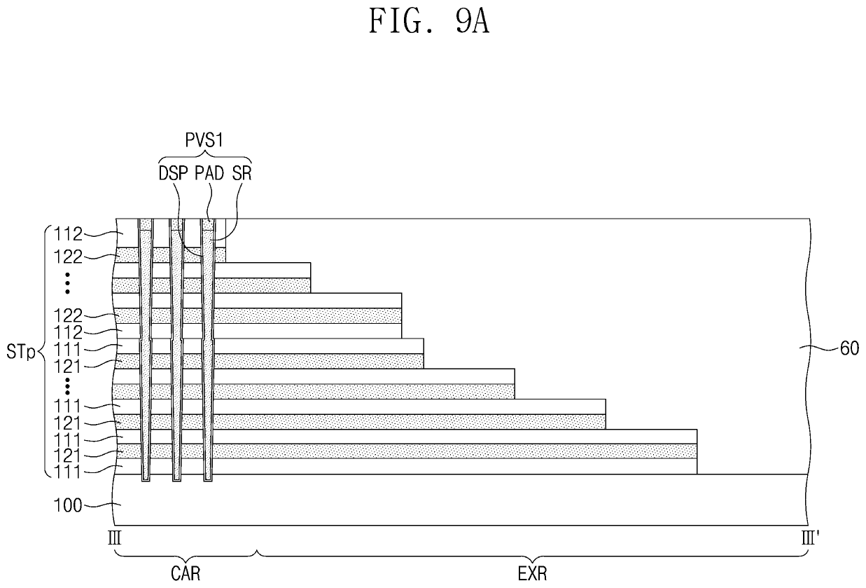

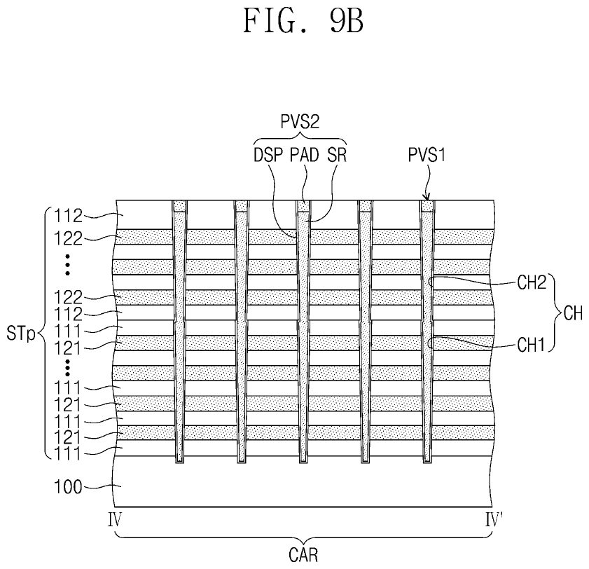

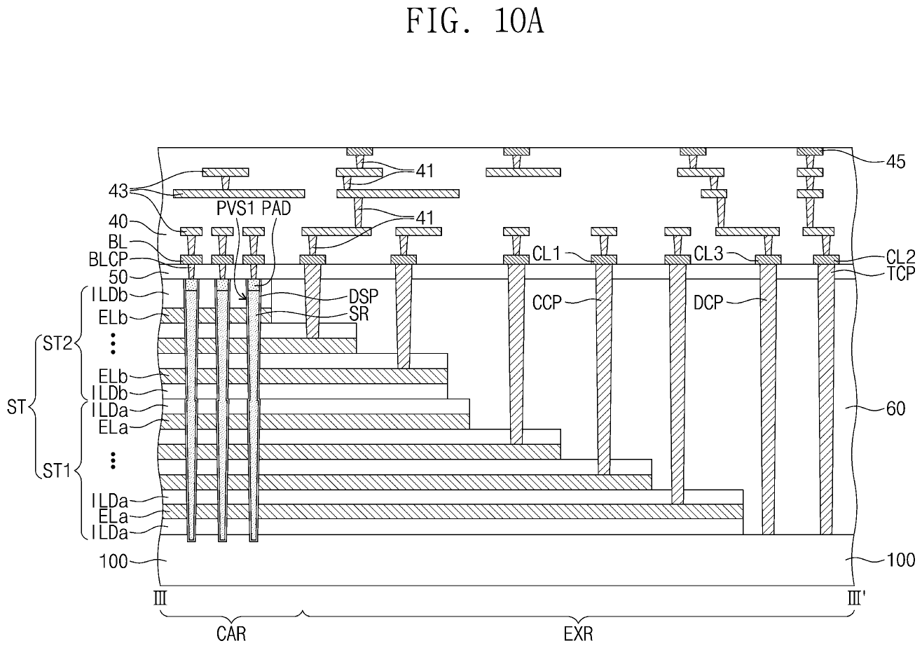

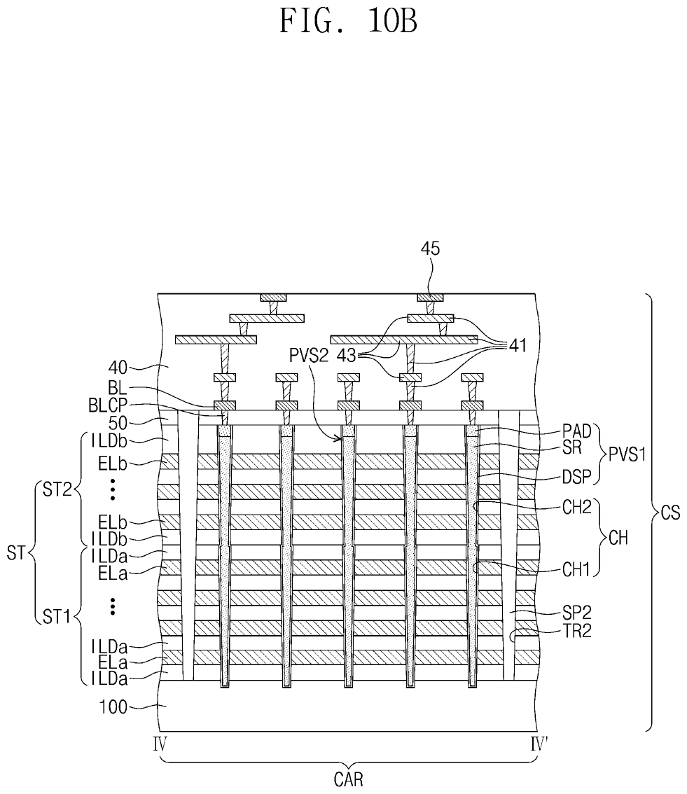

FIGS. 9A and 10A are sectional views, which are taken along a line III-III′ of FIG. 5 to illustrate a method of fabricating a three-dimensional semiconductor memory device according to some embodiments of the inventive concept. FIGS. 9B and 10B are sectional views, which are taken along a line IV-IV′ of FIG. 5 to illustrate a method of fabricating a three-dimensional semiconductor memory device according to some embodiments of the inventive concept.

Referring to FIGS. 8A and 8B, the peripheral circuit structure PS may be formed on the substrate 10. The formation of the peripheral circuit structure PS may include forming the device isolation layer 11 in the substrate 10 to define an active region, forming the peripheral transistors PTR on the active region of the substrate 10, and forming the peripheral contact plugs 31, the peripheral circuit interconnection lines 33, and the first bonding pads 35, which are electrically connected to the peripheral transistors PTR, and the first interlayer insulating layer 30 covering or being on them.

The first bonding pads 35 may be formed to have top surfaces that are substantially coplanar with a top surface of the first interlayer insulating layer 30. In the following description, the expression of “two elements are coplanar with each other” may mean that a planarization process may be performed on the elements. The planarization process may be performed using, for example, a chemical mechanical polishing (CMP) process or an etch-back process.

Referring to FIGS. 9A and 9B, first interlayer insulating layers 111 and first sacrificial layers 121 may be alternately stacked with one another on a carrier substrate 100. Thereafter, the first vertical channel holes CH1 may be formed to penetrate or extend in the first interlayer insulating layers 111 and the first sacrificial layers 121, and sacrificial layers may be formed to fill or be in the first vertical channel holes CH1. Second interlayer insulating layers 112 and second sacrificial layers 122 may be alternately stacked with one another on the first vertical channel holes CH1. The first and second sacrificial layers 121 and 122 may be formed of or include an insulating material different from the first and second interlayer insulating layers 111 and 112. The first and second sacrificial layers 121 and 122 may be formed of a material that can be etched with an etch selectivity with respect to the first and second interlayer insulating layers 111 and 112. For example, the first and second sacrificial layers 121 and 122 may be formed of or include silicon nitride, and the first and second interlayer insulating layers 111 and 112 may be formed of or include silicon oxide. In some embodiments, the first and second sacrificial layers 121 and 122 may have substantially the same thickness, and thicknesses of the first and second interlayer insulating layers 111 and 112 may vary depending on their vertical position.

Thereafter, the second vertical channel holes CH2 may be formed to penetrate or extend in the second interlayer insulating layers 112 and the second sacrificial layers 122 and to expose the sacrificial layers in the first vertical channel holes CH1. The second vertical channel holes CH2 may be overlapped with the first vertical channel holes CH1 in the third direction D3 and may be connected to the first vertical channel holes CH1 to constitute the vertical channel holes CH. The sacrificial layers, which are exposed by the second vertical channel holes CH2, may be removed, and then, preliminary vertical structures PVS1 and PVS2 may be formed in the vertical channel holes CH. Accordingly, the first and second interlayer insulating layers 111 and 112 and the first and second sacrificial layers 121 and 122, which are alternately stacked with one another, may form a preliminary stack STp. Each of the preliminary vertical structures PVS1 and PVS2 may include the data storage pattern DSP, a sacrificial pattern SR, and the conductive pad PAD. For example, the preliminary vertical structures PVS1 and PVS2 may extend in the preliminary stack STp on the carrier substrate 100. The data storage patterns DSP, the sacrificial patterns SR, and/or the conductive pads PAD may be formed in the vertical channel holes CH, respectively. The data storage pattern DSP may be formed to conformally cover or be on an inner side surface of each of the vertical channel holes CH. The sacrificial pattern SR may be formed on the data storage pattern DSP. An upper portion of the sacrificial pattern SR may be removed, and then, the conductive pad PAD may be formed to be in contact with an inner side surface of the data storage pattern DSP.

The sacrificial pattern SR may be formed of or include a material, which has an etch selectivity with respect to the data storage pattern DSP and the first and second interlayer insulating layers 111 and 112. In some embodiments, the sacrificial pattern SR may be formed of or include at least one of metallic materials (e.g., tungsten), carbon, or polysilicon.

A trimming process may be performed on the preliminary stack STp, which includes the first and second interlayer insulating layers 111 and 112 and the first and second sacrificial layers 121 and 122 that are alternately stacked with one another. The trimming process may include forming a mask pattern on the cell array region CAR and the cell array contact region EXR to cover a portion of a top surface of the preliminary stack STp, patterning the preliminary stack STp using the mask pattern as a patterning mask, reducing an area of the mask pattern, and patterning the preliminary stack STp using the mask pattern with the reduced area. In some embodiments, the steps of reducing the area of the mask pattern and patterning the preliminary stack STp using the mask pattern may be repeated several times during the trimming process. As a result of the trimming process, each of the first and second interlayer insulating layers 111 and 112 may be at least partially exposed to the outside, and the preliminary stack STp may have a staircase or stepped structure on the cell array contact region EXR. The staircase or stepped structure of the preliminary stack STp may be formed to expose a portion of the carrier substrate 100. Next, the fourth interlayer insulating layer 60 may be formed to cover or be on the staircase structure of the preliminary stack STp. In some embodiments, the fourth interlayer insulating layer 60 may be formed of or include silicon oxide.

Referring to FIGS. 5, 10A, and 10B, the third interlayer insulating layer 50 may be formed to cover or be on the top surface of the fourth interlayer insulating layer 60. The first and second trenches TR1 and TR2 may be formed to penetrate or extend in the third interlayer insulating layer 50, and the preliminary stack STp. The first and second trenches TR1 and TR2 may be extended from the cell array region CAR to the cell array contact region EXR. A depth of the first trench TR1 may be smaller than a depth of the second trench TR2. A bottom surface of the first trench TR1 may be located at a level that is higher than the top surface of the uppermost one of the first interlayer insulating layers 111. A bottom surface of the second trench TR2 may be located at a level that is lower than bottom surfaces of the preliminary vertical structures PVS1 and PVS2.

The first and second sacrificial layers 121 and 122, which are exposed through the first and second trenches TR1 and TR2, may be removed. In some embodiments, the removal of the first and second sacrificial layers 121 and 122 may be performed by a wet etching process using hydrofluoric acid (HF) and/or phosphoric acid (H₃PO₄) solution.

The first and second gate electrodes ELa and ELb may be formed to fill or be in empty regions that are formed by the removing of the first and second sacrificial layers 121 and 122. The first and second interlayer insulating layers 111 and 112 may be referred to as the first and second interlayer insulating layers ILDa and ILDb of the first and second stacks ST1 and ST2, and as a result, the stack ST including the first and second interlayer insulating layers ILDa and ILDb and the first and second gate electrodes ELa and ELb may be formed.

The first separation pattern SP1 and the second separation pattern SP2 may be formed to fill or be in the first trench TR1 and the second trench TR2, respectively. The first and second separation patterns SP1 and SP2 may be formed to have top surfaces that are substantially coplanar with a top surface of the third interlayer insulating layer 50.

The bit line contact plugs BLCP may be formed to penetrate or extend in the third interlayer insulating layer 50 in the cell array region CAR and to be in contact with top surfaces of the preliminary vertical structures PVS1 and PVS2. In the cell array contact region EXR, the cell contact plugs CCP may be formed to penetrate or extend in the third and fourth interlayer insulating layers 50 and 60 and to be in contact with the pad portions ELp (see FIG. 6A) of the first and second gate electrodes ELa and ELb. Each of the cell contact plugs CCP may be formed to penetrate or extend in at least a portion of a corresponding one of the first and second interlayer insulating layers ILDa and ILDb. The source contact plug DCP and the penetration contact plug TCP may be formed to penetrate or extend in the third and fourth insulating layers 50 and 60 in the cell array contact region EXR and may be connected to the carrier substrate 100.

At least two plugs of the cell contact plugs CCP, the source contact plug DCP, and the penetration contact plug TCP may be formed together (e.g., using the same process). The formation of the cell contact plugs CCP, the source contact plug DCP, and the penetration contact plug TCP may include an etching process that is performed to form holes penetrating or extending in the third and fourth interlayer insulating layers 50 and 60 and having a high aspect ratio.

In the cell array region CAR, the bit lines BL may be formed on the third interlayer insulating layer 50 to be in contact with the bit line contact plugs BLCP. In the cell array contact region EXR, the first to third conductive lines CL1, CL2, and CL3 may be formed on the third interlayer insulating layer 50.

The connection contact plugs 41, the connection circuit interconnection lines 43, and the second bonding pads 45, which are electrically connected to the bit lines BL and the first second, and/or third conductive lines CL1, CL2, and/or CL3 and the second interlayer insulating layer 40 covering or being on them may be formed on the third interlayer insulating layer 50. The second bonding pads 45 may be formed to have top surfaces that are substantially coplanar with a top surface of the second interlayer insulating layer 40. Accordingly, the cell array structure CS may be formed on the carrier substrate 100.

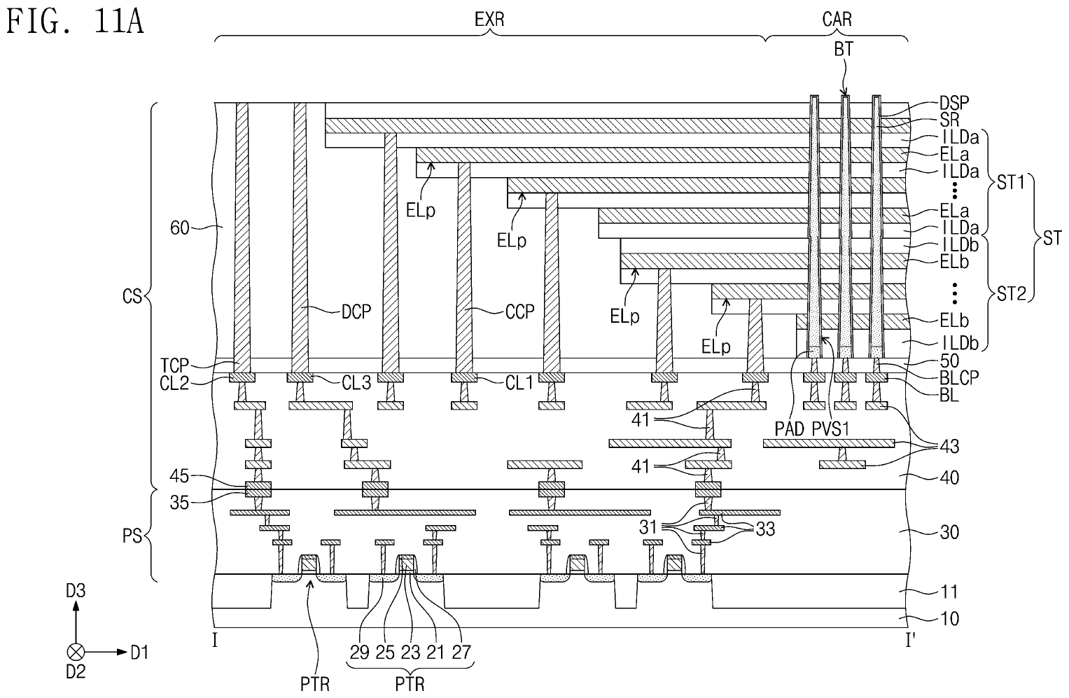

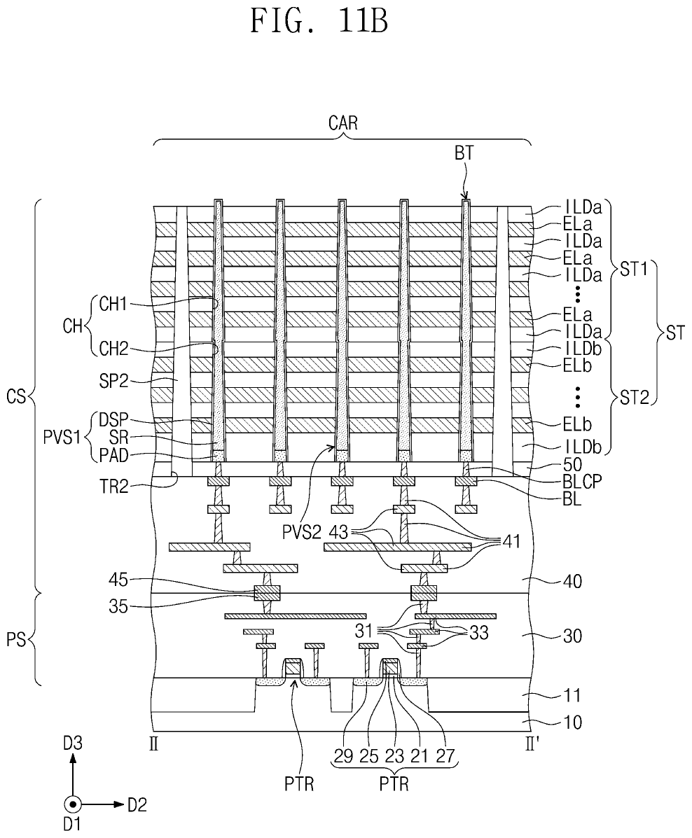

Referring to FIGS. 11A and 11B, the cell array structure CS, which is formed on the carrier substrate 100, may be bonded to the peripheral circuit structure PS, which is formed on the substrate 10 by the method described with reference to FIGS. 8A and 8B. In detail, the cell array structure CS may be attached to the peripheral circuit structure PS such that a first surface of the substrate 10, on which the peripheral circuit structure PS is formed, faces a first surface of the carrier substrate 100, on which the cell array structure CS is formed.

The carrier substrate 100 may be provided on the substrate 10 such that the cell array structure CS and the peripheral circuit structure PS face each other. The peripheral circuit structure PS and the cell array structure CS may be bonded to each other by the first bonding pads 35 and the second bonding pads 45, which are in contact with each other may be fused into one.

After the bonding of the first and second bonding pads 35 and 45, the carrier substrate 100 may be removed. In some embodiments, the removal of the carrier substrate 100 may include sequentially performing a planarization process, a dry etching process, and a wet etching process. As a result of the removal of the carrier substrate 100, upper portions BT of the preliminary vertical structures PVS1 and PVS2 may be exposed to the outside. As a result of the removal of the carrier substrate 100, upper portions of the source contact plug DCP and the penetration contact plug TCP may be exposed.

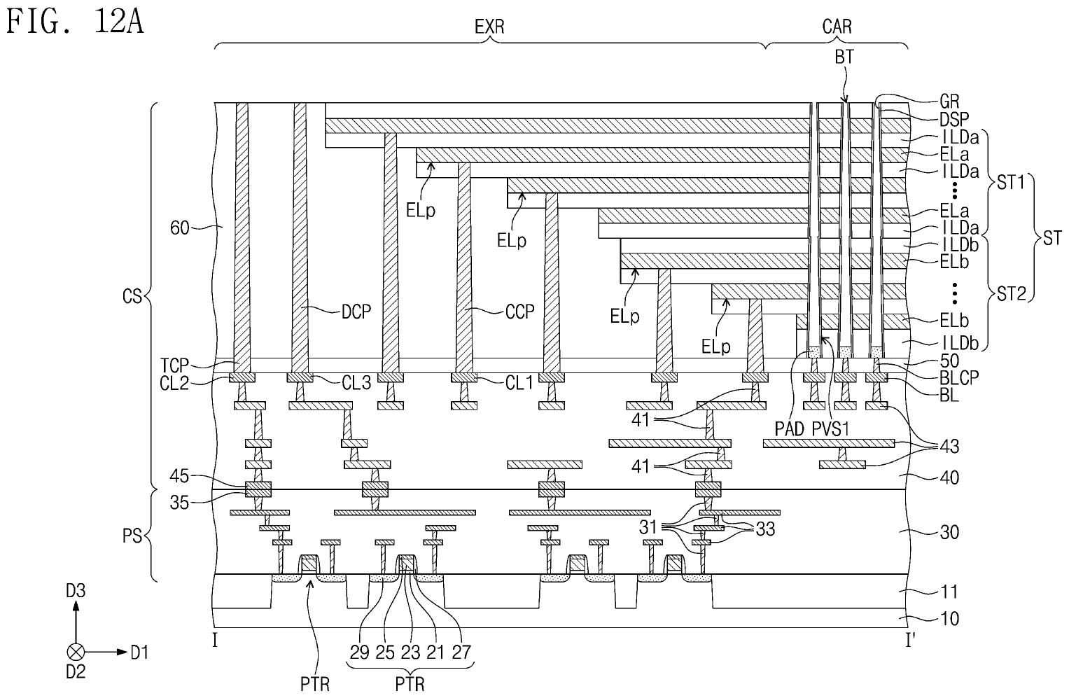

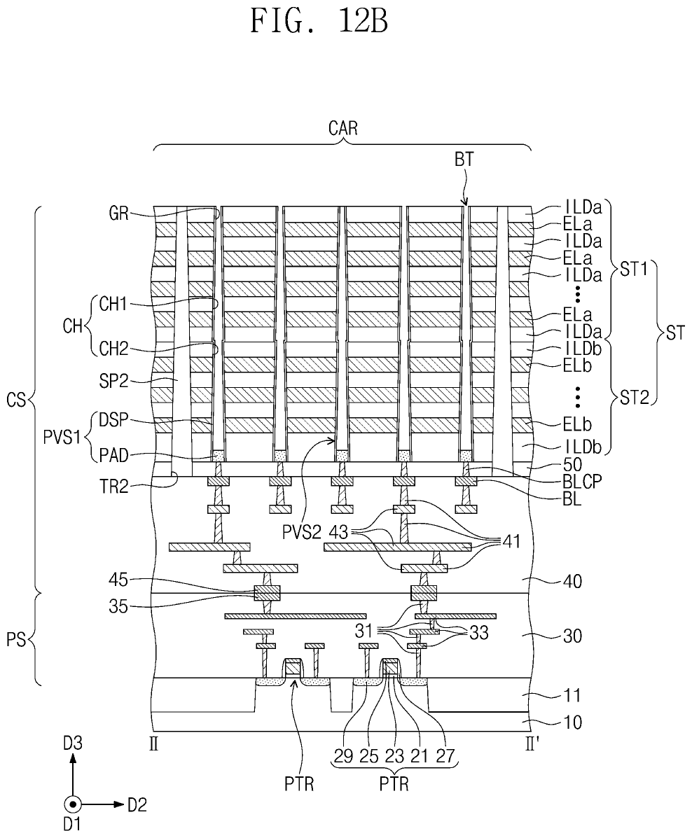

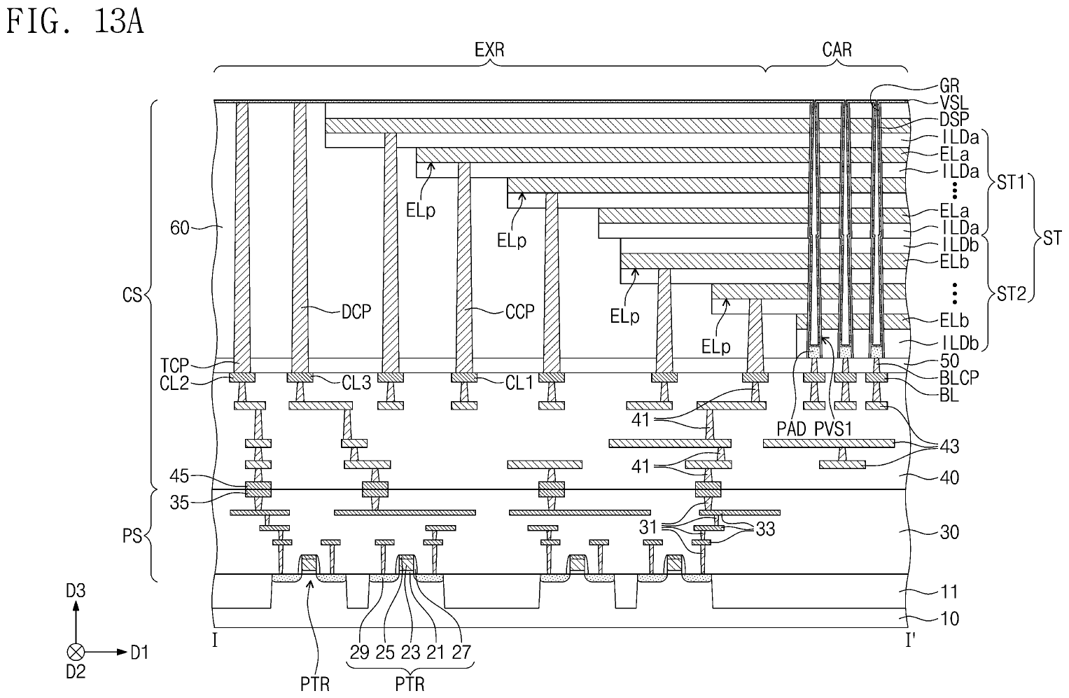

Referring to FIGS. 12A and 12B, the upper portions BT of the preliminary vertical structures PVS1 and PVS2 (e.g., the exposed upper portions of the data storage patterns DSP) may be removed to expose the sacrificial patterns SR in the vertical channel holes CH. The removal of the upper portions of the data storage patterns DSP may include performing a dry and/or wet etching process. Next, the sacrificial patterns SR may be selectively removed. The removal of the sacrificial patterns SR may include performing a wet etching process. As a result of the removal of the sacrificial patterns SR, the gap regions GR, which are defined by the inner side surfaces of the data storage patterns DSP, may be formed in the vertical channel holes CH, respectively. The conductive pads PAD may be exposed through the gap regions GR. For example, the removal of the sacrificial patterns SR may expose top surfaces of the conductive pads PAD.

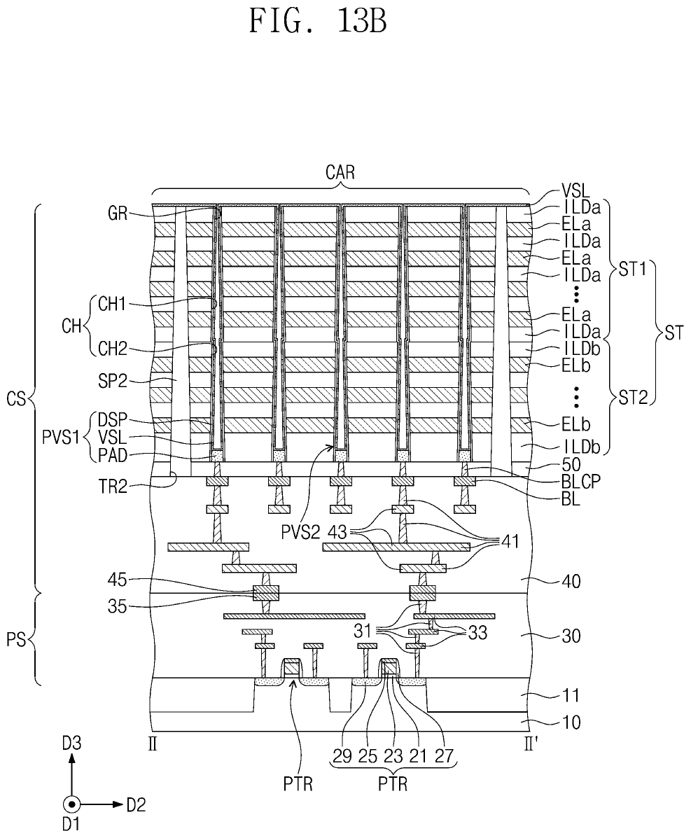

Referring to FIGS. 13A and 13B, the channel layer VSL may be formed to cover or be on the top surface of the stack ST and to extend into each of the vertical channel holes CH. The formation of the channel layer VSL may be performed after the formation of the gate electrodes ELa and ELb (e.g., after the process of bonding the cell array structure CS to the peripheral circuit structure PS described with reference to FIGS. 11A and 11B). The channel layer VSL may be a semiconductor layer, which is formed of at least one of group IV elements (e.g., SiGe or Ge), oxide semiconductor materials (e.g., zinc tin oxide (ZTO), amorphous or crystalline indium gallium zinc oxide (IGZO)), or group III-V elements (e.g., InAs or InGaAs). The channel layer VSL may be formed by an atomic layer deposition or chemical vapor deposition method. The channel layer VSL may be formed to have a substantially conformal profile and to cover or be on the uppermost one of the first interlayer insulating layers ILDa defining the top surface of the stack ST, the inner side surfaces of the data storage patterns DSP, and the top surfaces of the conductive pads PAD. In some embodiments, the channel layer VSL may be formed to partially fill or be in each of the vertical channel holes CH.

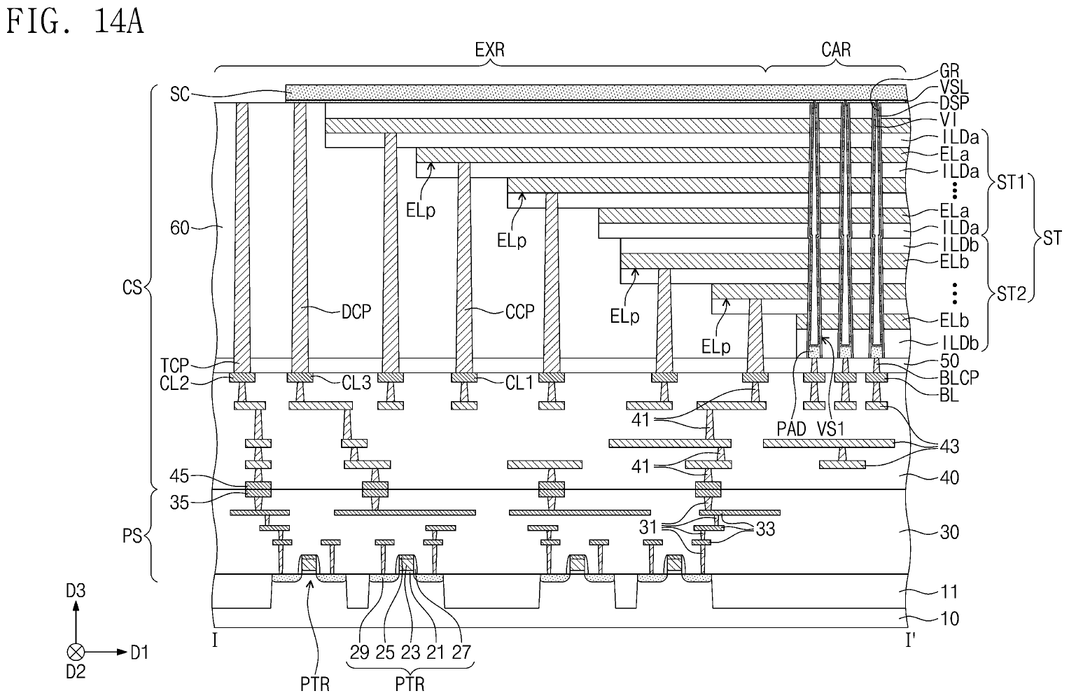

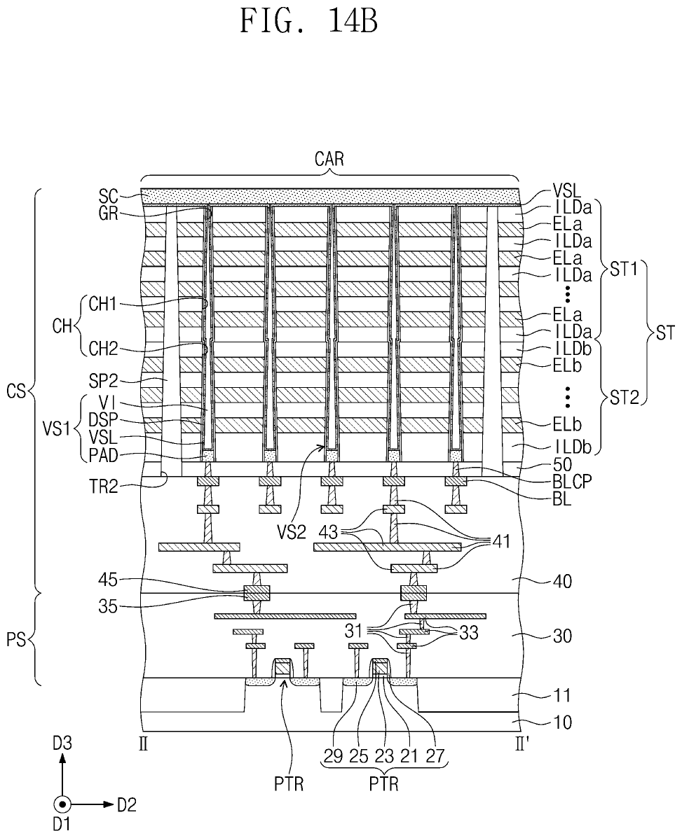

Referring to FIGS. 14A and 14B, the gap-fill insulating patterns VI may be formed to fill or be in the remaining spaces of the vertical channel holes CH, respectively. The gap-fill insulating patterns VI may be formed of a silicon oxide layer. The formation of the gap-fill insulating patterns VI may include forming an insulating layer to cover or be on the channel layer VSL and performing an etch-back process to remove the insulating layers outside the vertical channel holes CH. Thus, a top surface of the channel layer VSL may be exposed to the outside.

The source structure SC may be formed to cover or be on the channel layer VSL and the gap-fill insulating patterns VI. In some embodiments, the source structure SC may be formed of a polysilicon layer. Thereafter, the source structure SC and the channel layer VSL thereunder may be patterned to expose the top surface of the penetration contact plug TCP. As a result, the formation of the vertical structures VS1 and VS2 may be finished.

Referring back to FIGS. 5, 6A, and 6B, the fifth interlayer insulating layer 187 may be formed to cover or be on the source structure SC and the penetration contact plug TCP. The fifth interlayer insulating layer 187 may be formed of or include silicon oxide. The penetration via 196 may be formed to penetrate or extend in the fifth interlayer insulating layer 187 and to be connected to the penetration contact plug TCP. The penetration via 196 may be formed by forming a penetration hole to penetrate or extend in the fifth interlayer insulating layer 187 and filling the penetration hole with a metallic material. As an example, the penetration via 196 may be formed of or include at least one of tungsten, titanium, tantalum, or conductive metal nitrides thereof.

The back-side conductive pattern 197 may be formed on the penetration via 196. The back-side conductive pattern 197 may be formed by forming a metal layer to cover the penetration via 196, forming a mask pattern to cover the metal layer, and patterning the metal layer using the mask pattern as an etch mask. As a result, the back-side conductive pattern 197 may be formed to have a bottom surface whose width is larger than a top surface thereof. In some embodiments, the back-side conductive pattern 197 may be formed of or include aluminum. Thereafter, the sixth interlayer insulating layer 188 may be formed to cover or be on the fifth interlayer insulating layer 187 and to expose the back-side conductive pattern 197 (e.g., to expose a top surface of the back-side conductive pattern 197).

According to some embodiments of the inventive concept, the formation of the channel layer may be performed after the formation of the gate electrodes. In the case where materials having higher mobility than polysilicon are used as the channel layer, the semiconductor memory device may have improved electrical characteristics. However, for some of these materials, their characteristics may be degraded by subsequent high-temperature steps (e.g., at temperatures of 700° C. or higher), which are performed after the deposition step. According to some embodiments of the inventive concept, since the step of forming the channel layer is performed in a late stage of a fabrication process of the semiconductor memory device, it may be possible to prevent electrical characteristics of the channel layer from being deteriorated and to use materials with high mobility in the channel layer.

According to some embodiments of the inventive concept, since a step of forming a channel layer is performed in a late stage of a fabricating process of a semiconductor memory device, materials having good electrical characteristics and high mobility may be used in formation of the channel layer to prevent deterioration of electrical characteristics of the channel layer and improve mobility in the channel layer.

As used herein, the terms “comprises”, “comprising”, “includes”, “including”, “has”, “having” and any other variations thereof specify the presence of the stated features, integers, steps, operations, elements, and/or components, but do not preclude the presence or addition of one or more other features, integers, steps, operations, elements, components, and/or groups thereof.

While example embodiments of the inventive concept have been particularly shown and described, it will be understood by one of ordinary skill in the art that variations in form and detail may be made therein without departing from the scope of the attached claims.

What is claimed is:

1. A three-dimensional semiconductor memory device, comprising:
a substrate;
a peripheral circuit structure on the substrate; and
a cell array structure on the peripheral circuit structure, the cell array structure comprising:
a stack that includes interlayer insulating layers and conductive patterns alternately stacked with one another;
a source structure on the stack; and
a vertical structure that extends in the stack and is electrically connected to a bottom surface of the source structure,
wherein the vertical structure comprises a channel layer that includes first portions respectively in vertical channel holes extending in the stack, and a second portion that extends in a region between the stack and the source structure and is electrically connected to the first portions.

2. The semiconductor memory device of claim 1, wherein the channel layer comprises a material different from that of the source structure.

3. The semiconductor memory device of claim 2, wherein the channel layer comprises at least one of SiGe, Ge, ZTO, IGZO, InAs, or InGaAs.

4. The semiconductor memory device of claim 1, wherein the vertical structure further comprises gap-fill insulating patterns in the vertical channel holes, respectively, and
wherein top surfaces of the gap-fill insulating patterns are in contact with the bottom surface of the source structure.

5. The semiconductor memory device of claim 1, wherein the vertical structure further comprises conductive pads that are respectively in lower portions of the vertical channel holes, and
wherein lower portions of the first portions respectively extend along top surfaces of the conductive pads.

6. The semiconductor memory device of claim 1, wherein each of the first portions has a closed end pipe shape in a cross-sectional view.

7. The semiconductor memory device of claim 1, wherein the vertical structure further comprises:
gap-fill insulating patterns in the vertical channel holes, respectively; and
conductive pads in lower portions of the vertical channel holes, respectively, and
wherein the first portions extend in regions between the gap-fill insulating patterns and the conductive pads, respectively.

8. The semiconductor memory device of claim 1, wherein a top surface of the second portion is in contact with the bottom surface of the source structure.

9. The semiconductor memory device of claim 1, wherein the vertical structure further comprises data storage patterns that are respectively in the vertical channel holes, and
wherein a bottom surface of the second portion is on top surfaces of the data storage patterns.

10. The semiconductor memory device of claim 1, wherein the vertical structure further comprises gap-fill insulating patterns in the vertical channel holes, respectively, and
wherein top surfaces of the gap-fill insulating patterns are at substantially a same level as a top surface of the second portion in a direction perpendicular to the substrate, relative to the substrate.

11. The semiconductor memory device of claim 1, wherein a thickness of the second portion in a direction perpendicular to the substrate is less than that of the source structure.

12. The semiconductor memory device of claim 1, wherein the vertical structure further comprises gap-fill insulating patterns in the vertical channel holes, respectively, and
wherein top surfaces of the gap-fill insulating patterns are at a level higher than a top surface of the stack in a direction perpendicular to the substrate, relative to the substrate.

13. A three-dimensional semiconductor memory device, comprising:
a substrate;
a peripheral circuit structure on the substrate; and
a cell array structure on the peripheral circuit structure, the cell array structure comprising:
a cell array region;
a cell array contact region;
a stack that includes interlayer insulating layers and conductive patterns alternately stacked with one another;
a source structure on the stack;
a vertical structure that extends in the stack and is electrically connected to a bottom surface of the source structure;
cell contact plugs in the cell array contact region and electrically connected to the conductive patterns, respectively;
a source contact plug in the cell array contact region and electrically connected to the bottom surface of the source structure; and
bit lines electrically connected to the cell contact plugs,
wherein the vertical structure comprises a channel layer that includes first portions respectively in vertical channel holes extending in the stack, and a second portion that extends in a region between the stack and the source structure and is electrically connected to the first portions.

14. The semiconductor memory device of claim 13, wherein the channel layer comprises a material different from that of the source structure.

15. The semiconductor memory device of claim 13, wherein the vertical structure further comprises gap-fill insulating patterns in the vertical channel holes, respectively, and
wherein top surfaces of the gap-fill insulating patterns are in contact with the bottom surface of the source structure.

16. The semiconductor memory device of claim 13, wherein the vertical structure further comprises;
gap-fill insulating patterns in the vertical channel holes, respectively; and
conductive pads in lower portions of the vertical channel holes, respectively, and
wherein the first portions extend in regions between the gap-fill insulating patterns and the conductive pads, respectively.

17. An electronic system, comprising:
a three-dimensional semiconductor memory device that includes a substrate, a peripheral circuit structure on the substrate, and a cell array structure on the peripheral circuit structure, the cell array structure comprising a cell array region and a cell array contact region; and
a controller electrically connected to the three-dimensional semiconductor memory device through an input/output pad and configured to control the three-dimensional semiconductor memory device,
wherein the cell array structure further comprises:
a stack that includes interlayer insulating layers and conductive patterns alternately stacked with one another;
a source structure on the stack; and
a vertical structure that extends in the stack and is electrically connected to a bottom surface of the source structure, and
wherein the vertical structure comprises a channel layer that includes first portions respectively in vertical channel holes extending in the stack, and a second portion that extends in a region between the stack and the source structure and is electrically connected to the first portions.
